(19) United States
(12) Patent Application Publication
(10) Pub. No.: US 2012/0227779 A1
(43) Pub. Date: Sep. 13, 2012

(54) SYSTEM FOR THERMOELECTRIC CONVERTING TYPE SOLAR THERMAL POWER GENERATION

(75) Inventors: Lei Miao, Tianhe Guangzhou (CN); Sakae Tanemura, Moriyama-Ku Nagoya (JP); Gang Xu, Tianhe Guangzhou (CN); Yanqing Zhu, Tianhe Guangzhou (CN)

(73) Assignee: GUANGZHOU INSTITUTE OF ENERGY CONVERSION, CHINESE ACADEMY OF SCIENCE, Guangdong (CN)

(21) Appl. No.: 13/511,273

(22) PCT Filed: Mar. 26, 2010
(86) PCT No.: PCT/CN10/71343

§ 371 Date: May 22, 2012

(30) Foreign Application Priority Data
Jan. 29, 2010 (CN) 201010104932.2

(51) Int. Cl. H01L 35/30

(52) U.S. Cl. 136/206

(57) ABSTRACT

The invention discloses a solar thermal power generation system by thermoelectric conversion, comprising a sunlight-concentrating and receiving module, a solar tracking module, a photothermal-conversion module for absorbing sunlight then transforming sunlight into thermal energy and a combination of semiconductor thermoelectric module, the combination-type cooling module is under the semiconductor thermoelectric module. In the invention, TE module can directly convert solar thermal and waste heat to electricity without heat transfer medium, heat storage tank, turbine, and mechanical moving part, thus realizing small scale, compact system with high efficiency; Due to the adopting of low concentrating lens with tracking system and compound waste heat supplying module, thus reducing floor area and effectively improving temperature difference and power generating efficiency of the overall system. In comparison with that of traditional solar thermal power generation system, the new system kept the advantages, including: low investment and low maintenance cost. In comparison with that of solar cell power generation system, the system has the advantages: large power in small area and possible in stable output; furthermore a heating source apart from solar energy is introduced to guarantee the stable current supply.

### FIELD OF THE INVENTION

The present invention relates to solar thermal utilization field, and particular to a new type of solar thermal power generation system by thermoelectric conversion, belongs to the field of solar energy application.

### BACKGROUND OF THE INVENTION

At present, along with energy, environment and sustainable economic developments called as ‘tri-lemma’ problem increasingly obvious, renewable energy such as solar utilization is being paid more and more attention. Solar thermal utilization is a direct, original and important way in solar utilization field, especially the high cost of photovoltaic power plant in current situation, the developing of solar thermal power generation technology has a very important meaning. Compared with that of solar cell, the strong points of solar thermal power generation are summarized as: large scale, low cost (>MW plant), wide range spectrum utilization of solar radiation, against the damages from high temperature, strong radiation and inclement climate. Therefore, solar thermal power generation technology is considered as one of the most economic technology that can carry out great power and replace conventional energy.

Solar thermal power generation plant is a technology to achieve electricity working by thermodynamic cycle of engine through the thermal energy transformed from the solar irradiation by concentrating solar collector Solar thermal power plant comes into commerce step in developed country. In china, solar thermal power plant started late, and lots of funds were used to develop key technologies in period of ‘eleventh five’. There are three types of solar thermal power plants: solar towers, dish-stirling, parabolic trough, which focuses solar irradiation firstly, transforms photothermal conversion secondly, pass thermal using cycle medium, and finally producing steam force steam turbine to realize electricity.

The common thermal cycling fluids include melten salt, oil, water (steam), etc. The processes of the cycle of working fluid, storage, and thermal-electric conversion need a very long time. Also it needs huge complicated pipes, mechanism system and high maintenance cost.

### SUMMARY OF THE INVENTION

It is an object of the present invention to solve the above-described disadvantages such as high cost in heat transfer and electricity generation segments, high maintenance cost and low thermal utilization. In the present invention, a semiconductor thermoelectric unit replaces a thermal circulation part of the conventional solar thermal power system. And the present invention offers a new system with an integration of heat transfer, heat storage, heat exchange and electricity generation as a body without huge mechanical parts and mechanical maintenance and no moving component, thus realizing high efficiency and miniaturization of the system; Compared with conventional solar thermal power plant, the distinguished features of the new system are regarded as: small scale, compact system without huge heat transfer system, high output power density, low maintained cost, long operation hour, stable output (under solar+waste heat operation) and utilization of wide solar spectral range (0.3-2.5 μm) by absorption of the solar plate. Furthermore, the system has the characteristics of short energy pay-back time, low investment, low maintenance cost and energy-saving and environmental protection etc.

In order to achieve the above-described object, the present invention uses the technical scheme that a thermoelectric conversion solar thermal power generation system, comprising a sunlight-concentrating and receiving module, a solar tracking module, a photothermal-conversion module for absorbing sunlight and transforming sunlight into thermal energy. And a semiconductor thermoelectric module is under the photothermal-conversion module and the combination-type cooling module connecting with the semiconductor thermoelectric module.

Thermoelectric material is semiconductor material that can realize thermoelectric conversion by the movement of inside carrier, which can transform any form of thermal energy into electric energy without any complicated mechanical system and move unit. In comparison with that of solar thermal power and nucleus electric energy, the system has the advantages including: miniaturization, stable performance, no noise, no abrasion, no leaking, move agility, short energy pay-back time, great electric power density, low investment and low maintenance cost, etc.

The waste heating source module above the photothermal-conversion module includes airproof thermal insulating container, thermocouple and sensor switch for controlling thermocouple. The thermocouple is set at the lateral side of airproof thermal insulating container, the inlet of the waste heating source close to the thermocouple on the same lateral side of container, and the other side is the outlet of waste heating source. There is the solar transmission glass above the airproof thermal insulating container. The bottom of the container is the top of semiconductor module.

The waste heating source module has corresponding heating source pass. The supply of the waste heating source apart from solar energy can increase temperature difference, realize high efficiency and guarantee stable current supply. The medium of the waste heating source is high temperature waste gas or industry waste water with the temperature of 50˜100.

The photothermal-conversion module is solar selective absorbing film and directly coated on the surface of the semiconductor thermoelectric module. The solar selective absorbing film can transform sunlight into thermal energy effectively; whose material can be low temperature or mid- to high-temperature material. The selective absorbing film have different basic types, such as the type of intrinsic absorption, semiconductor absorption-reflection metal string, unsmooth surface, interference layer of electrolyte-metal, compound of dielectric-metal. The material can be provided by at least one type of the above films, but not limited the scope of the aboved material types.

The material of the solar selective absorbing film is the series of Ni—Al₂O₃, Cr—Cr₂O₃, or TiNO_{X}.

The semiconductor thermoelectric conversion module includes semiconductor thermoelectric unit, solar charge controller, storage battery and load. The top of the semiconductor thermoelectric unit connects to airproof thermal insulating container; the end of the semiconductor thermoelectric unit connects to a heat conductive plate with electrical insulator property, around of the semiconductor thermoelectric unit filled in thermal insulation layer with electrical insulator property. The semiconductor thermoelectric unit is made up of N-type and P-type semiconductor. Both the top and the end of N-type and/or P-type semiconductor connect to metal electrode. The semiconductor thermoelectric unit connects to solar controller, storage battery in series as a loop. Load is in parallel collection with semiconductor thermoelectric unit. P-type and N-type semiconductor constitutes a loop in series. Charge carriers in the materials will diffuse when one end of a conductor is at a different temperature than the other. Hot carriers diffuse from the hot side to the cold side, since there is a lower density of hot carriers at the cold side of the conductor, and vice versa. If the conductor were left to reach thermodynamic equilibrium, this process would result in heat being distributed evenly throughout the conductor. The movement of heat from one side to the other is a heat current and an electric current as charge carriers are moving. Different power and voltage can be obtained when connecting a plurality of the semiconductor units together. The voltage produced from a pair of P-N junction can be derived from V=α(T₁−T₂), where α is Seebeck coefficients decided by material property, T1 is the temperature at the hot junction and T2 is the temperature at the surface being cooled. The current can be given by

$$I = \frac{α ( {T}_{1} - {T}_{2} )}{R + r} ,$$

where R and r are the resistance of load and semi-conductor thermoelectric unit. Semiconductor thermoelectric units can be connected as a module to obtain different voltage. Greater output current can be obtained along with bigger temperature difference.

The output power density of the semiconductor thermoelectric unit (11) upwards 0.3 W/cm², the thermoelectric material for the semiconductor thermoelectric unit (11) is at least one of a tellurium series such as, Bi₂Te₃, PbTe, AgSbTe₂/GeTe, Bi₂Te₃/Sb₂Te₃, metal oxide such as, NaCoO₄, CaCoO₃, SrTiO₃/SrTiO₃:Nb, silicon compounds such as, SiGe, FeSi₂, Ba₈Si₄₆, Mg₂Si, MnSi_{1.73}, antimony series such as, ZnSb,Zn₄Sb₃,CoSb₃.

The sunlight-concentrating and receiving module includes condensing lens and supporting frame connected with condensing lens. The concentration ratio is from 10 to 500.

The condensing lens is flat Fresnel lens or spherical lens. The combination-type cooling module concludes cycle refrigerant and heat sink under semiconductor thermoelectric unit. When the cycle medium is refrigerant lots of refrigerant pipelines run through heat sink. One side of refrigerant pipelines through the outlet of cycle refrigerant connect to refrigerant storage box, the other side connect to the inlet of cycle refrigerant. While when the cycle medium is coolant by wind, lots of wind entrances run through heat sink. The entrances of wind connect to the inlet of the cycle cooling medium, the exit of wind through the outlet of cycle cooling medium connect to refrigerant storage box. The cooling medium can be one of the water, wind and other cold media. Hot water for daily life can be offered when using water as cooling medium.

The solar tracking module includes tracking control device and tracking frame. The tracking control device under sunlight-concentrating and receiving module is supported by tracking frame. The solar tracking module can be any one of the one dimension or three dimensions tracking mode, to guarantee the perpendicular incidence of the sunlight and getting of the largest heat current density in unit area.

The intention and innovation of the present invention is characterized in that a new compound power generation system of renewable energy and conventional energy. The present invention can offer electric power in small scale and also in large scale, which can be applied for power usage in family, residential estate, factory and other places of energy consumption for daily life. The innovations of the present invention are that (1) the effective combination of photothermal-conversion module and semiconductor thermoelectric unit, and (2) the effective combination of solar energy and waste heating energy.

Compared with the conventional solar thermal power generation plant, the present invention has the strong points as below:

(1) A semiconductor thermoelectric unit replaces a thermal circulation part of the conventional system with an integration of heat transfer, heat storage, heat exchange and electricity generation as a body without huge mechanical parts and mechanical maintenance and moving component, thus realizing high efficiency , small scale, low investment cost and low maintenance cost of the system.

(2) Compared with conventional solar, cell (photovoltaic) the distinguished features of the new system are regarded as: high output power density, the possibility of stable power output (under solar+waste heat operation) and utilization of wide solar spectral range (0.3-2.5 μm) by absorption of the solar plate.

### BRIEF DESCRIPTION OF THE DRAWINGS

FIG. 1 is a schematic diagram showing the whole system of the present invention;

FIG. 2 is a schematic view of the structure of Fresnel lens focusing and photothermal-conversion system;

FIG. 3 is a schematic view of the structure of spherical lens focusing and photothermal-conversion system;

FIG. 4 is a schematic view of the structure of water combination-type cooling system;

FIG. 5 is a schematic view of the structure of wind combination-type cooling system.

Sign of the Drawings: 1—condensing lens, 2—supporting frame, 3—tracking control device, 4—solar charge controller, 5—storage battery, 6—load, 7—refrigerant storage box, 8—inlet of cycle refrigerant, 9—outlet of cycle refrigerant, 10—tracking frame, 11—semiconductor thermoelectric unit, 12—thermal insulation layer with electrical insulator property, 13—thermocouple, 14—sensor switch, 15—inlet of the waste heating source, 16—outlet of the waste heating source, 17—solar transmission glass, 18—N-type semiconductor, 19—P-type semiconductor, 20—solar selective absorbing film, 21—metal electrode, 22—heat conductive plate with electrical insulator property, 23—airproof thermal insulating container, 24—spherical lens, 25—heat sink, 26—refrigerant pipelines, 27—entrance of wind, 28—exit of wind.

### DETAILED DESCRIPTION OF THE PREFERRED EMBODIMENT

The present invention will now be described by referring to the accompanying drawings that illustrate the preferred embodiments of the invention, from which its objects and features will be evident.

### Example 1

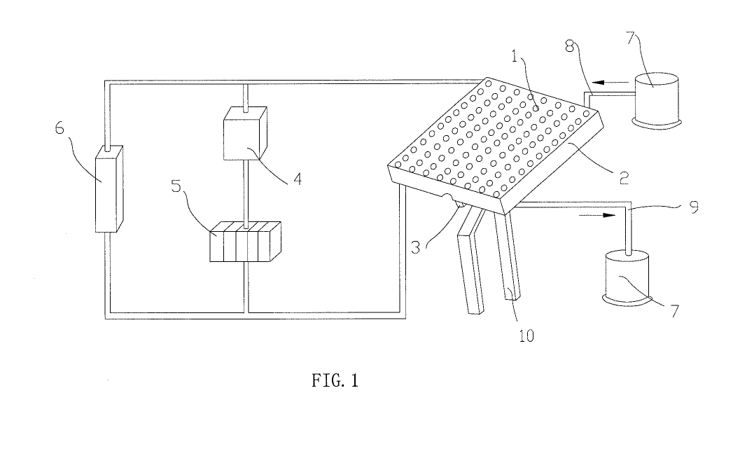

As shown in FIG. 1, a thermoelectric conversion solar thermal power generation system, comprising a sunlight-concentrating and receiving module, a solar tracking module below the sunlight-concentrating and receiving module; a photothermal-conversion module for absorbing sunlight and transforming photo energy into thermal energy, and the photothermal-conversion module is combined with a semiconductor thermoelectric module; And a semiconductor thermoelectric module is under the photothermal-conversion module and the combination-type cooling module connecting with the semiconductor thermoelectric module.

The structures of various modules are expatiated as below:

The sunlight-concentrating and receiving module includes condensing lens (1) and supporting frame (2) connected with condensing lens (1).

The solar tracking module includes tracking control device (3) and tracking frame (10). The tracking control device under sunlight-concentrating and receiving module is supported by tracking frame (10).

The photothermal-conversion module is solar selective absorbing film (20) directly coated on the surface of the semiconductor thermoelectric module. The material of the solar selective absorbing film (20) is the series of Ni—Al₂O₃, Cr—Cr₂O₃, or TiNOₓ.

The waste heating source module above the photothermal-conversion module (solar selective absorbing coating 20) includes airproof thermal insulating container 23, thermocouple 13 and sensor switch 14 for controlling thermocouple 19. The thermocouple is set at the lateral side of thermal insulating container 23, the inlet of the waste heating source 15 closes to thermocouple 13 on the same lateral side of container, and the other side is the outlet of the waste heating source 16. The top side of airproof thermal insulating container 23 is the solar transmission glass 17, and the bottom side of the container 23 is the top side of semiconductor thermoelectric module 11.

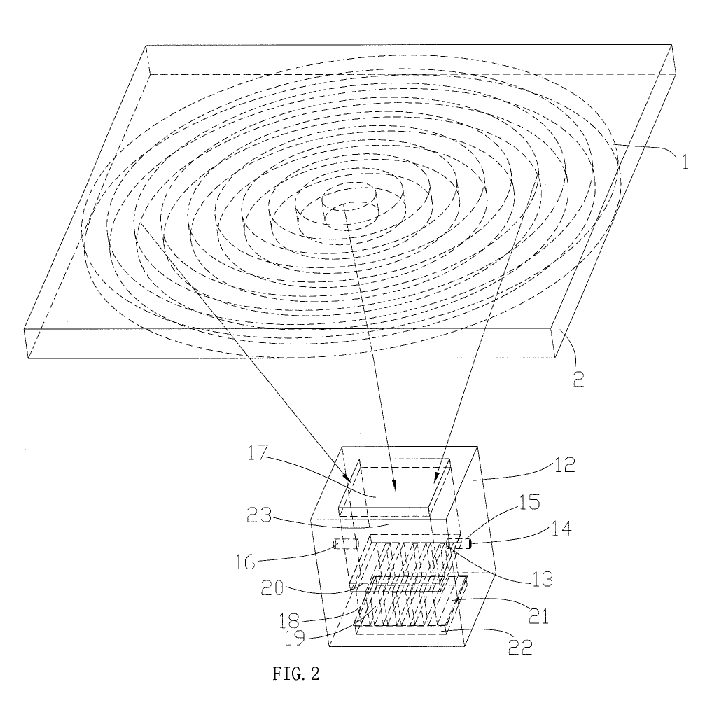

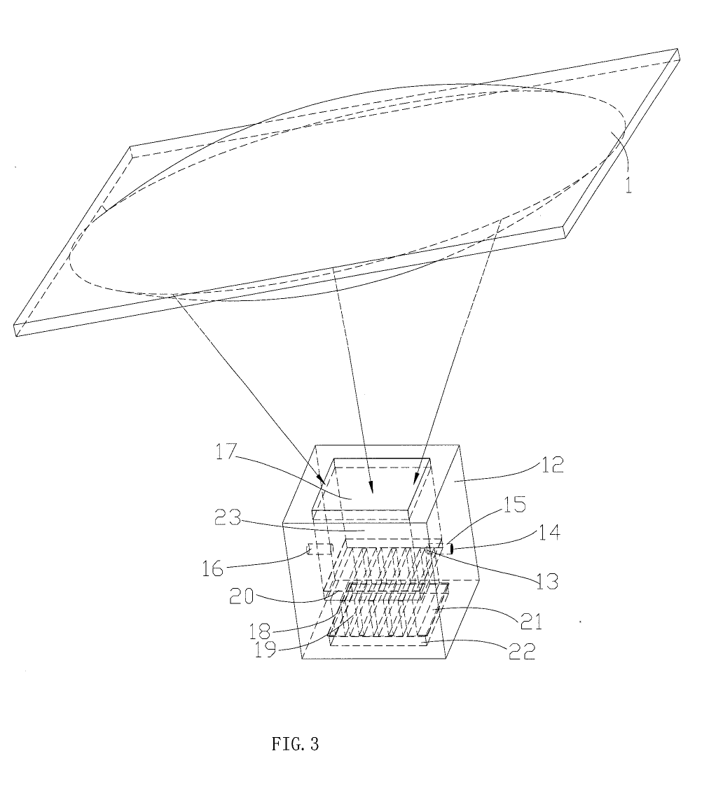

As shown in FIG. 2 or FIG. 3, the semiconductor thermoelectric modules include semiconductor thermoelectric unit (11), solar charge controller (4), storage battery (5) and load (6). The top of the semiconductor thermoelectric unit connects to airproof thermal insulating container (23); the end of the semiconductor thermoelectric unit connects to a heat conductive plate with electrical insulator property (22), around of the semiconductor thermoelectric unit (11) filled in thermal insulation layer with electrical insulator property (12). The semiconductor thermoelectric unit (11) is made up of N-type (18) and P-type (19) semiconductor. Both the top and the end of N-type and P-type semiconductor connect to metal electrode (21). The semiconductor thermoelectric unit (11) connects to solar charge controller (4), storage battery (5) in series as a loop. Load (6) is in parallel collection with semiconductor thermoelectric unit (11). The high output power density (upwards 0.3 W/cm²) of the semiconductor thermoelectric unit (11) could be provided by at least one of a tellurium series such as, Bi₂Te₃, PbTe, AgSbTe₂/GeTe, Bi₂Te₃/Sb₂Te₃, metal oxide such as, NaCoO₄, CaCoO₃, SrTiO₃/SrTiO₃:Nb, silicon compounds such as, SiGe , FeSi₂, Ba₈Si₄₆, Mg₂Si, MnSi_{1.73}, or antimony series such as, ZnSb,Zn₄Sb₃,CoSb₃, and not limited the aboved series materials.

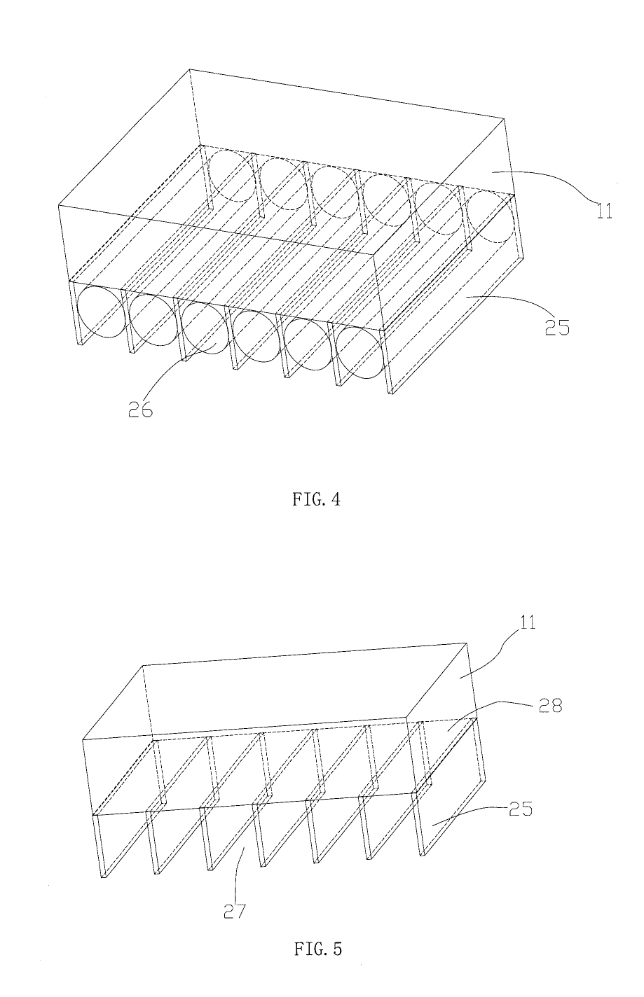

The combination-type cooling module concludes cycle refrigerant and heat sink 25 lie under semiconductor thermoelectric unit 11, as shown in FIG. 4. When the cycle medium is refrigerant, lots of refrigerant pipelines 26 run through heat sink 25. One side of refrigerant pipelines 26 through the outlet of cycle refrigerant 9 connect to refrigerant storage box 7, the other side connects to the inlet of cycle refrigerant 8. As shown in FIG. 5, while the cycle medium is coolant by wind, lots of wind entrances 27 run through heat sink 25. The wind entrances 27 connect to the inlet of the cycle refrigerant 8, the exit of wind 28 through the outlet of cycle refrigerant 9 connect to refrigerant storage box 7.

As shown in FIG. 2, the condensing lens 1 is flat Fresnel lens installed supporting frames 2. The whole system tracks the sun in three dimensions by solar tracking module including tracking control device 3. The sunlight is focused on Ni—Al₂O₃ solar selective absorbing film 20 by flat Fresnel lens with concentrating ratio of ten. The heat transforms form Ni—Al₂O₃ solar selective absorbing film to semiconductor thermoelectric unit 11 which made by antimony series (such as, Bi₂Te₃). The top of the semiconductor thermoelectric unit 11 is the heat of waste heating source and solar thermal energy, and the end of the semiconductor thermoelectric unit 11 go along water cooling; therefore the two sides produce temperature difference to obtain electric current. Then, the semiconductor thermoelectric unit 11, solar charge controller 4, storage battery 5 and load 6 work as a system loop. Refrigerant pipelines are arranged in cross to benefit to the heat dispersion of the cold side of the semiconductor thermoelectric unit, and also hot water for daily life can be offered. The waste heat source is offered from fuel electric power plant as assistant heat source.

### Example 2

As shown in FIG. 3, the condensing lens 1 is spherical lens 24 with concentrating ratio of 500 installed on the supporting frames 2. The whole system tracks the sun in three dimensions by solar tracking module including tracking control device 3. The sunlight is focused on TiNOₓ solar selective absorbing film 20 by spherical lens 24 with concentrating ratio of 500. The heat transforms form TiNOₓ solar selective absorbing film to semiconductor thermoelectric unit 11 which made by metal oxide (NaCoO₄). The top of the semiconductor thermoelectric unit 11 is the heat of waste heating source and solar thermal energy, and the bottom of the semiconductor thermoelectric unit 11 is coolant by wind; therefore the two sides produce temperature difference to obtain electric current. Then, the semiconductor thermoelectric unit 11, solar charge controller 4, storage battery 5 and load 6 work as a system loop. The waste heating source is offered by industry waste water in the temperature of 50˜100 as assistant heating source.

### Example 3

As shown in FIG. 2, the above mentioned condensing lens 1 is flat Fresnel lens with concentrating ratio of 100 installed on the supporting frames 2. The whole system tracks the sun in three dimensions by solar tracking module including tracking control device 3. The sunlight is focused to TiNOₓ solar selective absorbing film 20 by flat Fresnel lens with concentrating ratio of 100. The heat transforms form Cr—Cr₂O₃ solar selective absorbing film to semiconductor thermoelectric unit 11 which made by cobalt-antimony series (CoSb₃). The top of the semiconductor thermoelectric unit 11 is the heat of waste heating source and solar thermal energy, and the bottom of the semiconductor thermoelectric unit 11 go along wind cooling; therefore the two sides produce temperature difference to obtain electric current. Then, the semiconductor thermoelectric unit 11, solar charge controller 4, storage battery 5 and load 6 work as a system loop. The waste heating source is offered from industry waste water with the temperature of 50˜100 as assistant heating source.

### Example 4

As shown in FIG. 3, the condensing lens 1 is spherical lens 24 installed on the supporting frames 2. The whole system tracks the sun in three dimensions by solar tracking module including tracking control device 3. The sunlight is focused to TiNOₓ solar selective absorbing film 20 by spherical lens with concentrating ratio of 500. The heat transforms form Ni—Al₂O₃ solar selective absorbing film to semiconductor thermoelectric unit 11 which made by silicon series (SiGe). The top of the semiconductor thermoelectric unit 11 is the heat of waste heating source and solar thermal energy, and the bottom of the semiconductor thermoelectric unit 11 go along refrigerant (zero fluorin cold-producing medium R410A); therefore the two sides produce temperature difference to obtain electric current. Then, the semiconductor thermoelectric unit 11, solar charge controller 4, storage battery 5 and load 6 work as a system loop. The waste heating source is offered from fuel electric power plant as assistant heating source.

It should be emphasized that the above-described embodiments can be combined freely. Many variations and modifications may be made to the above-described embodiment(s) of the invention without departing substantially from the spirit and principles of the invention. All such modifications and variations are intended to be included herein within the scope of this disclosure and the present invention and protected by the following claims.

1. A solar thermal power generation system by thermoelectric conversion, comprising a sunlight-concentrating and receiving module, a solar tracking module below the sunlight-concentrating and receiving module; the characteristics of this system include: a photothermal-conversion module for absorbing sunlight and transforming photo energy into thermal energy, and the photothermal-conversion module is combined with a semiconductor thermoelectric module; and the combination-type cooling module is under the semiconductor module for generating large temperature difference.

2. A solar thermal power generation system by thermoelectric conversion as claimed in claim 1, characterized in that there is a waste heating source module above the photothermal-conversion module, which includes airproof thermal insulating container (23), thermocouple (13) and sensor switch (14) for controlling the thermocouple (13). The thermocouple (13) is set at the lateral side of thermal insulating container (23), the inlet of the waste heating source (15) closes to the thermocouple (13) on the same lateral side of container, and the other side is the outlet of the waste heating source (16). There is the solar transmission glass (17) above the airproof thermal insulating container (23).

3. A solar thermal power generation system by thermoelectric conversion as claimed in claim 1, characterized in that the photothermal-conversion module is solar selective absorbing film (20) and directly coated on the surface of the semiconductor thermoelectric module.

4. A solar thermal power generation system by thermoelectric conversion as claimed in claim 2, characterized in that the material of the solar selective absorbing film is the series of Ni—Al₂O₃, Cr—Cr₂O₃, or TiNOₓ.

5. A solar thermal power generation system by thermoelectric conversion as claimed in claim 1, characterized in that the semiconductor thermoelectric conversion module includes semiconductor thermoelectric unit (11), solar charge controller (4), storage battery (5) and load (6). The top of the semiconductor thermoelectric unit (11) connects to the airproof thermal insulating container (23); the end of the semiconductor thermoelectric unit (11) connects to a heat conductive plate with electrical insulator property (22), around of the semiconductor thermoelectric unit (11) filled in thermal insulation layer with electrical insulator property (12). The semiconductor thermoelectric unit (11) is made up of N-type (18) and P-type semiconductor (19). Both the top and the end of N-type and/or P-type semiconductor connect to metal electrode (21). The semiconductor thermoelectric unit (11) connects to solar charge controller (4), storage battery (5) in series as a loop. Load (6) is in parallel collection with semiconductor thermoelectric unit (11).

6. A solar thermal power generation system by thermoelectric conversion as claimed in claim 4, characterized in that the output power density of the semiconductor thermoelectric unit (11) upwards 0.3 W/cm² , the thermoelectric material for the semiconductor thermoelectric unit (11) is provided by tellurium compound series such as, Bi₂Te₃, PbTe, AgSbTe₂/GeTe, Bi₂Te₃/Sb₂Te₃, metal oxide series such as, NaCoO₄, CaCoO₃, SrTiO₃/SrTiO₃:Nb, silicon compounds such as, SiGe, FeSi₂, Ba₈Si₄₆, Mg₂Si, MnSi_{1.73}, antimony series such as, ZnSb,Zn₄Sb₃,CoSb₃.

7. A solar thermal power generation system by thermoelectric conversion as claimed in claim 1, characterized in that sunlight-concentrating and receiving module includes condensing lens (1) and supporting frame (2) connected with condensing lens.

8. A solar thermal power generation system by thermoelectric conversion as claimed in claim 6, characterized in that the condensing lens (1) is flat Fresnel lens or spherical lens. The combination-type cooling module concludes cycle refrigerant and heat sink (25) under semiconductor thermoelectric unit (11). When the cycle medium is refrigerant lots of refrigerant pipelines (26) run through the heat sink (25). One side of refrigerant pipelines (26) through the outlet of cycle refrigerant (9) connect to refrigerant storage box (7), the other side connect to the inlet of cycle refrigerant (8). While when the cycle medium is coolant by wind, lots of wind entrances (27) run through heat sink (25). The entrances of wind connect to the inlet of the cycle cooling medium (8), the exit of wind (28) through the outlet of cycle cooling medium (9) connect to refrigerant storage box (7).

9. A solar thermal power generation system by thermoelectric conversion as claimed in claim 1, characterized in that the solar tracking module includes tracking control device (3) and tracking frame (10). The tracking control device under sunlight-concentrating and receiving module is supported by tracking frame (10).
